(19) United States
(12) Patent Application Publication
(10) Pub. No.: US 2025/0210506 A1
(43) Pub. Date: Jun. 26, 2025

(54) PASSIVATION BOUNDARY DEFECTS FOR REDUCED LEAKAGE CURRENT CAPACITOR DIELECTRIC MATERIALS

(71) Applicant: Intel Corporation, Santa Clara, CA (US)

(72) Inventors: Kihyun Kim, Chandler, AZ (US); Marcel Wall, Phoenix, AZ (US); Shayan Kaviani, Phoenix, AZ (US); Darko Grujicic, Chandler, AZ (US); Rengarajan Shanmugam, Tempe, AZ (US); Srinivas Pietambaram, Chandler, AZ (US); Dilan Seneviratne, Phoenix, AZ (US); Rahul Manepalli, Chandler, AZ (US); Mahdi Mohammadighaleni, Phoenix, AZ (US)

(73) Assignee: Intel Corporation, Santa Clara, CA (US)

(21) Appl. No.: 18/391,168

(22) Filed: Dec. 20, 2023

(51) Int. Cl. H01L 23/522; H01G 4/08

(52) U.S. Cl. CPC H01L 23/5223; H01G 4/085; H01L 23/5226; H10D 1/694

(57) ABSTRACT

Apparatuses, capacitor structures, systems, and techniques related to capacitors having passivation boundary defects within a polycrystalline dielectric material of the capacitor are discussed. The polycrystalline dielectric material includes crystalline grains of a first composition having grain boundaries between the crystalline grains. At some of the grain boundaries, the polycrystalline dielectric material includes amorphous passivation material having a second composition.

### BACKGROUND

The integrated circuit industry is continually striving to produce ever faster, smaller, and more efficient integrated circuit devices, packages, and systems for use in various electronic products. For advanced packaging integration, switching frequency and circuit power increases cause operation voltage margins to decrease due to leakage current in capacitor dielectric materials. This leakage current problem can degrade the entire functionality of advanced packaging modules.

Currently, higher dielectric constant materials are being sought. However, such materials have difficulties in manufacturability, reliability, and others. Furthermore, such higher dielectric constant materials can necessitate higher work function electrode materials. Current prospective higher work function electrode materials again have difficulties in manufacturability including the need for high temperature processing, which can degrade the capacitor dielectric and other materials of the capacitor and the assembly.

It is with respect to these and other considerations that the present improvements have been needed. Such improvements may become critical as the desire to provide improved integrated circuit devices, packages, and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a cross-sectional view of an example capacitor having a capacitor dielectric with passivation boundary defects;

FIG. 2 illustrates an enlarged view of a portion of the dielectric material of the capacitor of FIG. 1;

FIG. 3 illustrates an atomic level view of a portion of the dielectric material of the capacitor of FIG. 1;

FIG. 4 illustrates a cross-sectional side view of an exemplary deep trench capacitor having a polycrystalline dielectric material including an amorphous passivation material at grain boundaries of the polycrystalline dielectric material;

FIG. 5 illustrates a cross-sectional top-down view of the deep trench capacitor of FIG. 4;

FIG. 6 illustrates a stacked capacitor structure including a dielectric layer having a polycrystalline dielectric material including an amorphous passivation material at grain boundaries of the polycrystalline dielectric material;

FIG. 7 illustrates a stacked capacitor structure similar to the stacked capacitor structure of FIG. 6 with metal vias coupled to electrodes of the stacked capacitor structure;

FIG. 8 illustrates a cross-sectional top-down view of the substrate of the stacked capacitor structure of FIG. 7;

FIG. 9 is a flow diagram illustrating methods for forming a capacitor having a polycrystalline dielectric material including an amorphous passivation material at grain boundaries of the polycrystalline dielectric material;

FIGS. 10A, 10B, 10C, 10D, and 10E are cross-sectional views of capacitor structures evolving as the methods of FIG. 9 are practiced;

FIG. 11 illustrates an example microelectronic device assembly including a component that includes a capacitor having a polycrystalline dielectric material including an amorphous passivation material at grain boundaries of the polycrystalline dielectric material;

FIG. 12 illustrates exemplary systems employing a capacitor with a capacitor dielectric having passivation boundary defects to reduce leakage current; and

FIG. 13 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 95% of the particular material or component and “pure” indicates not less than 99% of the particular material or component. Unless otherwise indicated, such material percentages are based on atomic percentage. As used herein, the terms “monolithic”, “monolithically integrated”, and similar terms indicate the components of the monolithic overall structure form an indivisible whole not reasonably capable of being separated.

Apparatuses, systems, capacitor structures, assemblies, and techniques are described herein related to capacitors deploying a dielectric material having passivation boundary defects at grain boundaries of crystallite grains of the dielectric material to impede leakage current in the capacitor device.

As discussed, in advanced packaging integration, switching frequency and circuit power increases can cause operation difficulties in capacitors due to the leakage current in the capacitor dielectric materials, which degrades the functionality of the packaging modules. In some embodiments, the capacitor is deployed as a deep trench capacitor (DTC) in a glass trench of a glass substrate, and the discussed materials and techniques provide passivation boundary defects of DTCs in a glass trench. However, the capacitor materials discussed herein may be deployed in any suitable capacitor structure. As discussed herein, a capacitor includes a dielectric material between two electrodes. The dielectric material is polycrystalline, having grains of crystalline material separated by grain boundaries therebetween. At some or all of the grain boundaries, an amorphous passivation material is formed to impede leakage current that would otherwise flow along the grain boundaries. For example, high-k dielectrics such as zirconium oxide, hafnium oxide, and others may be formed such that they have a polycrystalline structure or morphology. The polycrystalline structure of such dielectric materials includes a relatively high grain boundary density, and grain boundaries are the main path of leakage current between the electrodes of the capacitor. Leakage current, in turn, is the primary problem regarding undesirable capacitance density decrease. By providing amorphous passivation material at the grain boundaries, leakage current is reduced, and capacitor performance is improved. As discussed herein below, such passivation material may be formed at the grain boundaries using cyclic atomic layer deposition (ALD) processing to inject the passivation material in the dielectric material grain boundaries.

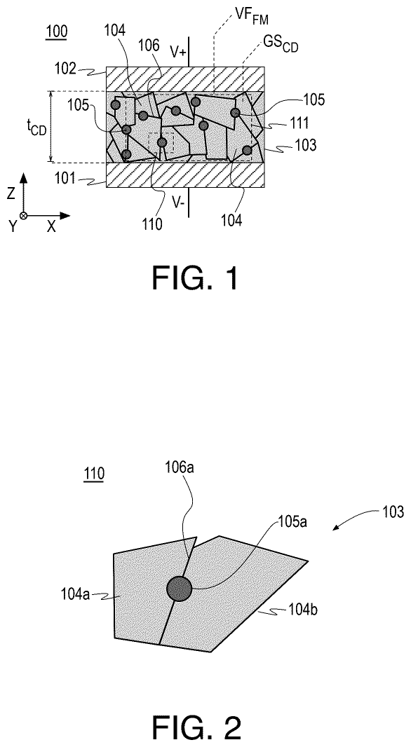

FIG. 1 illustrates a cross-sectional view of an example capacitor 100 having a capacitor dielectric with passivation boundary defects, arranged in accordance with at least some implementations of the present disclosure. As shown in FIG. 1, capacitor 100 includes a dielectric material 103 between electrodes 101, 102. As discussed in detail herein, dielectric material 103 is a dielectric material, film, or layer including polycrystalline zirconium oxide, ZrO₂ (i.e., a material including zirconium and oxygen), polycrystalline hafnium oxide, HfO₂ (i.e., a material including hafnium and oxygen), or other polycrystalline high-k dielectric material.

As used herein, the term high-k dielectric material indicates a material having a dielectric constant of not less than 20. The term crystalline indicates a material or portion of a material having a highly ordered structure inclusive of a crystal lattice such that the material has a uniform spatial lattice orientation. The term polycrystalline indicates a material or portion of a material having a number of crystalline grains (or crystallites) that meet at grain boundaries between the crystalline grains, which are two-dimensional defects in the crystalline structure. The term grain indicates a crystal region or portion of material having the discussed crystalline properties. The term amorphous indicates a material or portion of a material having no periodic or ordered structure. Herein the term polycrystalline is used to indicate a material inclusive of crystal grains, having grain boundaries therebetween, and amorphous material at one or more of the grain boundaries.

In some embodiments, capacitor 100 may also include interfacial layers between dielectric material 103 and one or both of electrodes 101, 102. Herein such interfacial layers are defined as part of electrodes 101, 102. Furthermore, any suitable capacitor or capacitor structure such as capacitor 100 and those discussed elsewhere herein may be incorporated in any suitable circuitry or any other higher-level apparatus, system, structure, or device such as those discussed herein without limitation. Notably, circuitry and devices deploying offers the advantage of low leakage current.

As shown, capacitor 100 includes a first or bottom electrode 101. Electrode 101 may include any suitable conductive material such as a metal. In some embodiments, electrode 101 is or includes titanium nitride (TiN, e.g., titanium and nitrogen). In some embodiments, electrode 101 is or includes silicon oxide (SiO₂, e.g., silicon and oxygen). In some embodiments, electrode 101 is or includes titanium oxide (TiO₂, e.g., titanium and oxygen). In some embodiments, electrode 101 is or includes tungsten (W), tantalum nitride (TaN, e.g., tantalum and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt). Similarly, second or top electrode 102 may include any suitable conductive material such as a metal. In some embodiments, electrode 102 is or includes titanium nitride (TiN, e.g., titanium and nitrogen). In some embodiments, electrode 102 is or includes silicon oxide (SiO₂, e.g., silicon and oxygen). In some embodiments, electrode 102 is or includes titanium oxide (TiO₂, e.g., titanium and oxygen). In some embodiments, electrode 102 is or includes tungsten (W), tantalum nitride (TaN, e.g., tantalum and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt). The material(s) deployed in bottom electrode 101 and top electrode 102 may be the same or they may be different.

As shown, dielectric material 103 (or a dielectric layer, dielectric material layer, dielectric film, or the like) is between electrode 101 and electrode 102. In some embodiments, dielectric material 103 is directly on one or both of electrode 101 and electrode 102. In some embodiments, an intervening layer may be between dielectric and one or both of electrode 101 and electrode 102.

Dielectric material 103 is a polycrystalline material including a number of crystalline grains 104 (or crystallites) of crystalline material. In some embodiments, crystalline grains 104 are zirconium oxide, ZrO₂ (e.g., a crystalline material including zirconium and oxygen). In some embodiments, crystalline grains 104 are hafnium oxide, HfO₂ (e.g., a crystalline material including zirconium and oxygen). For example, each of crystalline grains 104 may have a first composition including oxygen and one of hafnium or zirconium.

In some embodiments, crystalline grains 104 are stoichiometric zirconium oxide having about one-third zirconium atoms and two-thirds oxygen atoms. In some embodiments, the first composition of crystalline grains 104 is not less than 33 atomic percent zirconium and not less that 66 atomic percent oxygen. In some embodiments, the first composition of crystalline grains 104 is not less than 32 atomic percent zirconium and not less that 65 atomic percent oxygen. In some embodiments, the first composition of crystalline grains 104 is not less than thirty atomic percent zirconium and not less than sixty atomic percent oxygen. In some embodiments, the first composition of crystalline grains 104 is not less than twenty atomic percent zirconium and not less than twenty atomic percent oxygen.

In some embodiments, crystalline grains 104 are stoichiometric hafnium oxide having about one-third hafnium atoms and two-thirds oxygen atoms. In some embodiments, the first composition of crystalline grains 104 is not less than 33 atomic percent hafnium and not less that 66 atomic percent oxygen. In some embodiments, the first composition of crystalline grains 104 is not less than 32 atomic percent hafnium and not less that 65 atomic percent oxygen. In some embodiments, the first composition of crystalline grains 104 is not less than thirty atomic percent hafnium and not less than sixty atomic percent oxygen. In some embodiments, the first composition of crystalline grains 104 is not less than twenty atomic percent hafnium and not less than twenty atomic percent oxygen.

Crystalline grains 104 may have any suitable grain size GS_{CD} (grain size, capacitor dielectric), which may be measured using any suitable technique or techniques such as a distance across a centerline of crystalline grains 104, a maximum distance across crystalline grains 104, or the like. In some embodiments, the grain size GS_{CD} is in the range of about 500 nm to 15 microns; however, other grain sizes may be used. As discussed herein below the grain size of crystalline grains 104 may be based on the process parameters used to form them.

At boundaries or locations between crystalline grains 104, grain boundaries 106 are defined. As discussed, grain boundaries 106 are two-dimensional defects in a crystalline structure and are inherent or defined by the polycrystalline nature of dielectric material 103. At some or all of grain boundaries 106, dielectric material 103 includes filler material 105. Filler material 105 may also be characterized as passivation material, boundary defect material, passivation boundary defect material, amorphous material, or the like. Notably, filler material 105 is amorphous and has a second composition different than the first composition of crystalline grains 104. As used herein, a different composition indicates that one or more constituents of a first composition are absent from a second composition and vice versa.

In some embodiments, filler material 105 has a high crystallization or crystallinity temperature such that filler material 105 has an amorphous structure as crystalline grains 104 are formed. Filler material 105 may be any suitable amorphous material that impedes current flow along grain boundaries 106. In some embodiments, filler material 105 is substantially pure or pure silicon. For example, filler material 105 may be not less than 95 percent silicon or not less than 99 percent silicon. In some embodiments, filler material 105 is not less than 99.9 percent silicon. In some embodiments, filler material 105 is not less than ninety percent silicon. In some embodiments, filler material 105 is an amorphous dielectric material. In some embodiments, filler material 105 is boron nitride (e.g., includes boron and nitrogen). In some embodiments, filler material 105 is carbon doped silicon oxide, SiCOH (e.g., includes carbon, silicon, and oxygen).

As shown, across a thickness t_{CD} of dielectric material 103 and any suitable shape in the x-y plane, a volume 111 of dielectric material 103 may be defined. Within volume 111 of dielectric material 103, filler material 105 may have any suitable volume fraction VF_{FM} (volume fraction, filler material) of the entirety of volume 111. For example, the volume of filler material divided by the total volume of a particular volume sample of dielectric material 103 may define volume fraction VF_{FM}. In some embodiments, the volume fraction of filler material 105 is in the range of 0.5 percent to 7 percent (e.g., 0.5%≤VF_{FM}≤7%). In some embodiments, the volume fraction of filler material 105 is in the range of one percent to five percent (e.g., 1%≤VF_{FM}≤5%). In some embodiments, the volume fraction of filler material 105 is in the range of two percent to four percent (e.g., 2%≤VF_{FM}≤4%). Other volume fractions of filler material 105 may be used.

FIG. 2 illustrates an enlarged view 110 of a portion of dielectric material 103, arranged in accordance with at least some implementations of the present disclosure. As shown in enlarged view 110, dielectric material 103 may include a first crystalline grain 104a and a second crystalline grain 104b separated by a grain boundary 106a between first crystalline grain 104a and second crystalline grain 104b. Furthermore, a filler material 105a is at grain boundary 106a and between first crystalline grain 104a and second crystalline grain 104b. As used herein, at a grain boundary indicates the filler material or portion of filler material is at an identified two-dimensional defect that separates and defines first crystalline grain 104a and second crystalline grain 104b or within 200 nm of the identified two-dimensional defect that separates and defines first crystalline grain 104a and second crystalline grain 104b.

In the illustrated example, filler material 105a is substantially spherical. However, filler material 105a may have any suitable shape. Furthermore, in the example of FIG. 2, filler material 105a is isolated within a portion of grain boundary 106a. That is, filler material 105a does not extend along an entirety of grain boundary 106a between first crystalline grain 104a and second crystalline grain 104b. In other examples, filler material 105a extends along an entirety of grain boundary 106a or nearly all of grain boundary 106a such as not less than ninety percent of grain boundary 106a or not less than half of grain boundary 106a.

As discussed, grain boundary 106a, along with other grain boundaries 106 of dielectric material 103, are the primary path of leakage current between electrode 101 and electrode 102. Filler material 105a impedes or blocks the current path to reduce leakage current in dielectric material 103. Notably, electron mobility in amorphous materials is much lower than that of polycrystalline materials. Filler material 105 passivates the defects (e.g., grain boundaries 106) of dielectric material 103 to reduce leakage current. As discussed below, in some embodiments, dielectric material 103 may be deployed as a high-k dielectric material or interface for deep trench capacitors (DTC) on glass trench structures to reduce leakage current in DTC packaging applications. Also as discussed below, a cyclic ALD process may be deployed to inject amorphous material into high-k dielectric grain boundaries.

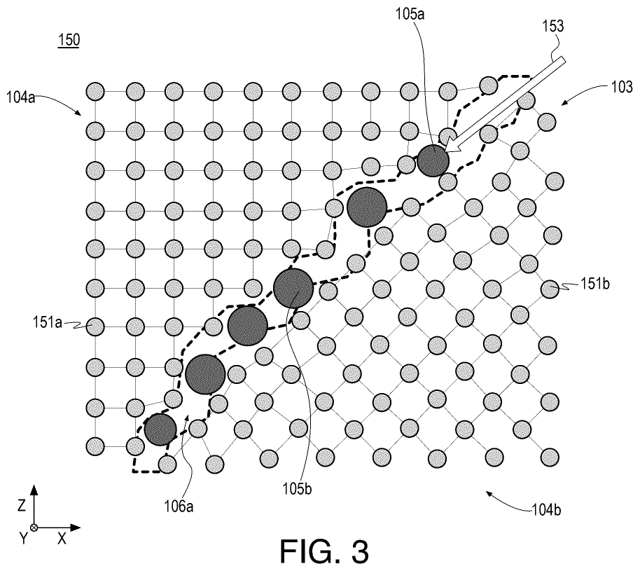

FIG. 3 illustrates an atomic level view 150 of a portion of dielectric material 103, arranged in accordance with at least some implementations of the present disclosure. As shown in FIG. 3, dielectric material 103 includes first crystalline grain 104a having a uniform spatial orientation lattice 151a such that lattice 151a is a lattice of atoms forming zirconium oxide, hafnium oxide, or other crystalline dielectric material. Dielectric material 103 further includes second crystalline grain 104b having a uniform spatial orientation lattice 151b such that lattice 151b is again a lattice of atoms forming zirconium oxide, hafnium oxide, or other crystalline dielectric material. As shown, lattice 151a and lattice 151b may have differing orientations in dielectric material 103. First crystalline grain 104a and second crystalline grain 104b are separated by grain boundary 106a therebetween as discussed above. Atomic level view 150 makes evident the nature of grain boundary 106a being a two-dimensional defect between first crystalline grain 104a and second crystalline grain 104b (i.e., between lattice 151a and lattice 151b).

Also as shown in FIG. 3, grain boundary 106a provides a potential leakage current path 153 through dielectric material 103 (and between electrode 101 and electrode 102). Absent filler materials 105a, 105b, potential leakage current path 153 reduces capacitance density and degrades capacitor performance. As shown, in dielectric material 103, filler materials 105a, 105b, which provide a second material composition and a second phase (i.e., amorphous) relative to first crystalline grain 104a and second crystalline grain 104b, impedes or stops potential leakage current path 153 to increase grain boundary resistance and to restrain the long-range movement of electrons, thereby reducing leakage current. By using filler materials 105, dielectric material 103 has low dielectric loss and improved stability.

In FIG. 3, a number of filler materials 105a, 105b are along grain boundary 106a. In the illustrated example, each of filler materials 105a, 105b is substantially spherical. However, filler materials 105a, 105b may have any suitable shape. Also as shown, in some embodiments, filler materials 105a, 105b have differing volumes such that some of filler materials 105a, 105b are larger than others. In some embodiments, a filler material is a monolithic material that extends along all of or a portion of grain boundary 106a. In some embodiments, a monolithic filler material extends along an entirety of grain boundary 106a or nearly all of grain boundary 106a such as not less than ninety percent of grain boundary 106a or not less than half of grain boundary 106a. In other embodiments, as shown, filter materials 105 are separated by voids or gaps therebetween.

Discussion now turns to deployment of dielectric material 103 in a capacitor structure. Dielectric material 103 may be deployed in any suitable capacitor context such as in MIM (metal-insulator-metal) capacitors, plate capacitors, stacked capacitors, deep trench capacitors, interdigitated capacitors, or others.

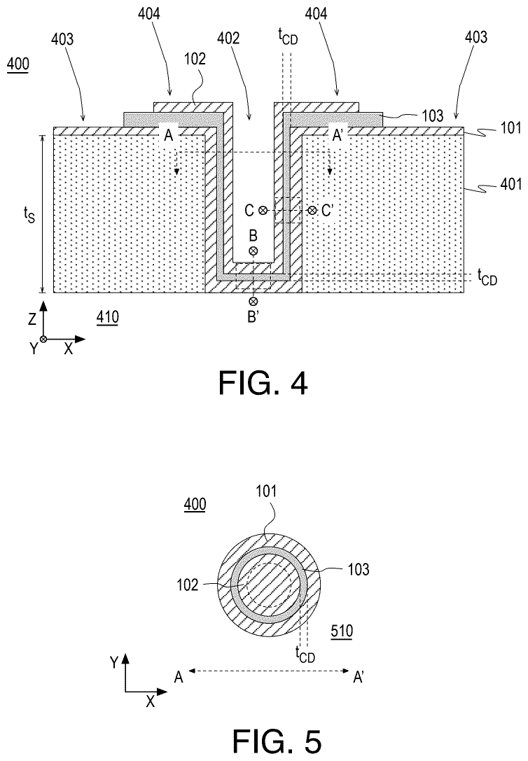

FIG. 4 illustrates a cross-sectional side view 410 of an exemplary deep trench capacitor 400 having a polycrystalline dielectric material including an amorphous passivation material at grain boundaries of the polycrystalline dielectric material, arranged in accordance with some embodiments of the disclosure. FIG. 5 illustrates a cross-sectional top-down view 510 of exemplary deep trench capacitor 400 having a polycrystalline dielectric material including an amorphous passivation material at grain boundaries of the polycrystalline dielectric material, arranged in accordance with some embodiments of the disclosure. As shown, cross-sectional top-down view 510 of FIG. 5 is taken at plane A-A′ in FIG. 4.

As shown, deep trench capacitor 400 may be deployed within an opening or trench 402 of a substrate 401. Trench 402 may extend partially or entirely through a thickness t_{S} of substrate 401. In some embodiments, substrate 401 is a glass substrate such as a layer of glass (e.g., a glass core). In some embodiments, substrate 401 is an amorphous solid glass layer. In some embodiments, substrate 401 is a layer of glass, which, for example, is one of aluminosilicate, borosilicate, alumino-borosilicate, silica, and fused silica. The layer of glass may include one or more of additives including Al₂O₃, B₂O₃, MgO, CaO, SrO, BaO, SnO₂, Na₂O, K₂O, P₂O₃, ZrO₂, Li₂O, Ti, or Zn. For example, the layer of glass may include an additive including one or more of aluminum, boron, magnesium, calcium, strontium, barium, tin, sodium, potassium, phosphorous, zirconium, lithium, titanium, or zinc. In some embodiments, the layer of glass may include silicon and oxygen and one or more of aluminum, boron, magnesium, calcium, strontium, barium, tin, sodium, potassium, phosphorous, zirconium, lithium, titanium, and zinc. In some embodiments, the layer of glass includes at least 23 percent silicon and at least 26 percent oxygen by weight, and further includes at least 5 percent aluminum by weight. In some embodiments, the layer of glass is rectangular in shape in plan view, as shown in FIG. 8. However, other shapes may be used. In some embodiments, substrate 401 is absent any organic adhesive or other organic material. In some embodiments, substrate 401 has a thickness t_{S} in the range of 50 microns to 1.4 mm (i.e., in the z-direction). For example, a glass layer of substrate 401 may have a thickness t_{S} in the range of 50 microns to 1.4 mm. In some embodiments, substrate is a multi-layer glass substrate (e.g., a coreless substrate having a glass layer with a thickness in the range of 25 microns to 50 microns). Other substrate materials may be used.

Deep trench architectures increase capacitor surface area, and deep trench capacitor 400 may have a U-shape (as shown) or a V-shape in cross-section. As shown, deep trench capacitor 400 includes electrode 101, electrode 102, and dielectric material 103 therebetween. As shown with respect to cross-sectional top-down view 510, in some embodiments, one or more of electrode 101, electrode 102, and dielectric material 103 have an annular shape having an inner and outer shape that are substantially circular. However, other shapes such as rectangular, square, ovular, and others may be used. Deep trench capacitor 400 is coupled to other devices using metal interconnects as discussed herein below. Although illustrated with respect to deep trench capacitor 400, the pertinent characteristics of electrode 101, electrode 102, and dielectric material 103 may be deployed in any capacitor or capacitor structure context herein such as a planar capacitor architecture, a stacked capacitor architecture, or the like.

As shown, deep trench capacitor 400 includes electrode 101, which may be a first or a bottom electrode. Electrode 101 may include any suitable material discussed above and may have portions 403 that extend onto a top surface of substrate 401 for electrical connection by a via, for example. Similarly, deep trench capacitor 400 includes electrode 102, which is a second or top electrode. Electrode 102 may also include any suitable conductive material discussed above and may have portions 404 that extend onto a top surface of substrate 401 for electrical connection by a via, for example.

Dielectric material 103 is between electrode 101 and electrode 102. In some embodiments, dielectric material 103 is directly on one or both of electrode 101 and electrode 102. In some embodiments, an intervening layer may be between dielectric material 103 and one or both of electrode 101 and electrode 102. Dielectric material 103 includes any materials and characteristics discussed above. Notably, FIGS. 1, 2, and 3 may illustrate a portion of deep trench capacitor 400 taken at cross sectional plane B-B′ or C-C′.

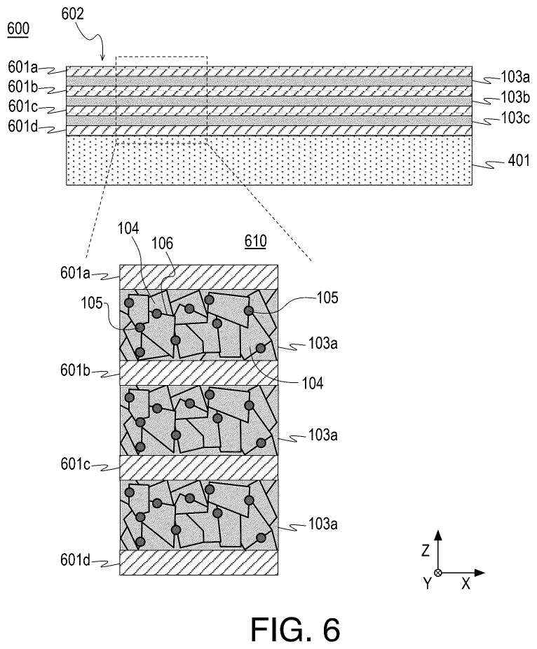

FIG. 6 illustrates a stacked capacitor structure 600 including a dielectric layer having a polycrystalline dielectric material including an amorphous passivation material at grain boundaries of the polycrystalline dielectric material, arranged in accordance with some embodiments of the disclosure. As shown in FIG. 6, stacked capacitor structure 600 may include a multilayer stack 602 having layers of electrodes 601a, 601b, 601c, 601d interleaved with dielectric materials 103a, 103b, 103c. For example, multilayer stack 602 of electrodes 601a, 601b, 601c, 601d interleaved with dielectric materials 103a, 103b, 103c may be formed on or over substrate 401.

As shown in enlarged view 610, one, some, or all of dielectric materials 103a, 103b, 103c may have any characteristics discussed herein with respect to dielectric material 103. For example, each of dielectric materials 103a, 103b, 103c may include crystalline grains 104 of a high-k dielectric material such as zirconium oxide or hafnium oxide, and filler material 105 at grain boundaries 106 between crystalline grains 104. In some embodiments, the characteristics of dielectric materials 103a, 103b, 103c are the same. In some embodiments, one or more characteristics of dielectric materials 103a, 103b, 103c are different.

For example, one more of dielectric materials 103a, 103b, 103c may include zirconium oxide crystalline grains 104 while one or more other layers of dielectric materials 103a, 103b, 103c include hafnium oxide crystalline grains 104. Furthermore, one or more of dielectric materials 103a, 103b, 103c may include filler material 105 of a first composition (i.e., one of silicon, boron nitride, or carbon doped silicon oxide) while one or more other layers of dielectric materials 103a, 103b, 103c include filler material 105 of a second composition (i.e., another of silicon, boron nitride, or carbon doped silicon oxide). In some embodiments, one or more of dielectric materials 103a, 103b, 103c may include filler material 105 of a third composition, and so on. In some embodiments, a grain size of crystalline grains 104 may also be varied between dielectric materials 103a, 103b, 103c.

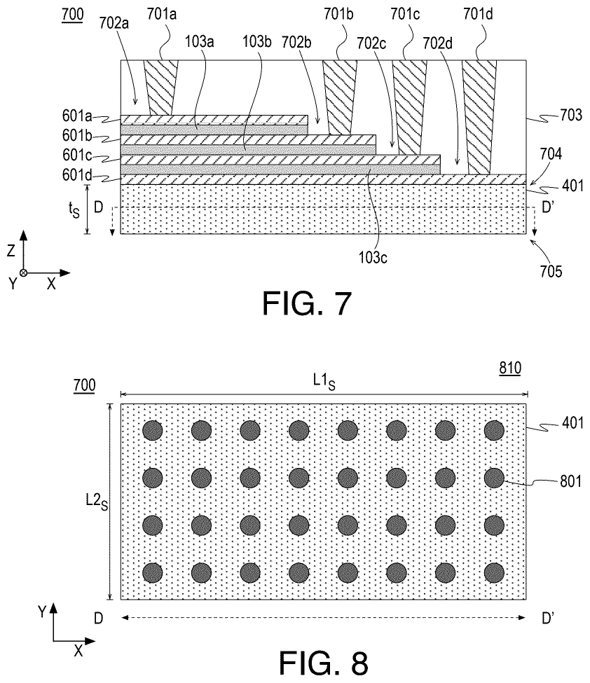

FIG. 7 illustrates a stacked capacitor structure 700 similar to stacked capacitor structure 600 with metal vias 701a, 701b, 701c, 701d coupled to electrodes 601a, 601b, 601c, 601d of stacked capacitor structure 700, arranged in accordance with some embodiments of the disclosure. As shown in FIG. 7, electrodes 601a, 601b, 601c, 601d and dielectric materials 103a, 103b, 103c may be patterned to expose and/or define regions 702a, 702b, 702c, 702d of electrodes 601a, 601b, 601c, 601d, respectively. Such regions 702a, 702b, 702c, 702d may be defined or formed using any suitable technique or techniques such as lithography and etch techniques as known in the art.

Subsequently, metal vias 701a, 701b, 701c, 701d, embedded in insulator material 703, may then be formed. For example, a bulk layer of insulator material 703 may first be formed and then patterned with openings corresponding to metal vias 701a, 701b, 701c, 701d. The openings may then be filled with metal and polished to form metal vias 701a, 701b, 701c, 701d. Other fabrication techniques may be used.

Metal vias 701a, 701b, 701c, 701d illustrate top-side contact of electrodes 601a, 601b, 601c, 601d. Such metal vias 701a, 701b, 701c, 701d may then be coupled to metallization layers over metal vias 701a, 701b, 701c, 701d and/or to outside devices. In addition, electrode 601d may be contacted by a back-side and/or substrate 401 may include vias extending therethrough for coupling to outside devices.

FIG. 8 illustrates a cross-sectional top-down view 810 of substrate 401 of stacked capacitor structure 700, arranged in accordance with some embodiments of the disclosure. As shown, cross-sectional top-down view 810 of FIG. 8 is taken at plane D-D′ in FIG. 7. With reference to FIGS. 7 and 8, in some embodiments, substrate 401 has a rectangular cross-sectional shape in shape in plan view (i.e., in the x-y plane). However, substrate 401 may have other cross-sectional shapes.

As discussed herein, substrate 401 may be a glass layer or substrate in some embodiments. As shown, substrate 401 may be a layer of glass having a rectangular prism volume (i.e., defined by the rectangular cross-sectional shape in the x-y plane and a depth in the z-dimension). In some embodiments, substrate 401 is a layer of glass having a thickness t_{S} in a range of 50 um to 1.4 mm, a first length L1_{S} (length 1, substrate) in a range of 10 mm to 250 mm, and a second length L1_{S} (length 2 or width, substrate) in a range of 10 mm to 250 mm, such that the first length is perpendicular to the second length.

Furthermore, substrate 401 may include one or more metal vias 801 (or, simply, vias) extending vertically (i.e., in the z-dimension) through substrate 401. For example, one or more of metal vias 801 may couple to an electrode such as electrode 601d of a capacitor structure such as stacked capacitor structure 700. Although illustrated with respect to metal vias 801 contacting stacked capacitor structure 700, metal vias 801 may contact any electrode of any capacitor or capacitor structure discussed herein. As shown, in some embodiments, substrate 401 may be or include a layer of glass including a rectangular prism volume (i.e., t_{S}×L1_{S}×L2_{S}) and one or more metal vias 801 extending from a first side 704 of the rectangular prism volume to a second side 705 of the rectangular prism volume. Metal vias 801 may include any suitable metal such as copper, tungsten, or others.

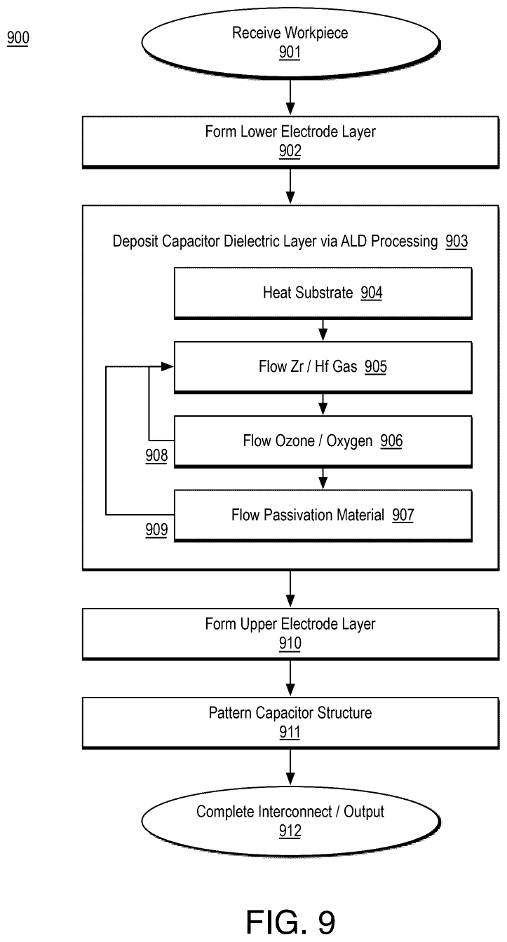

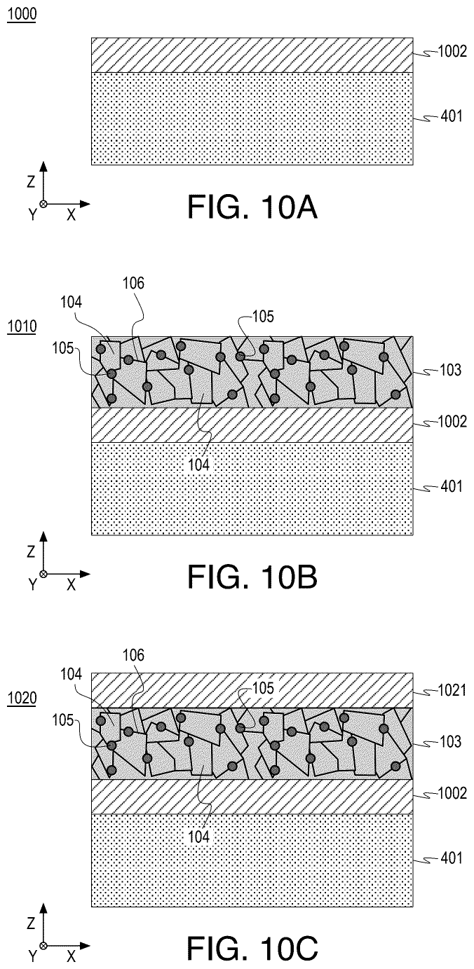

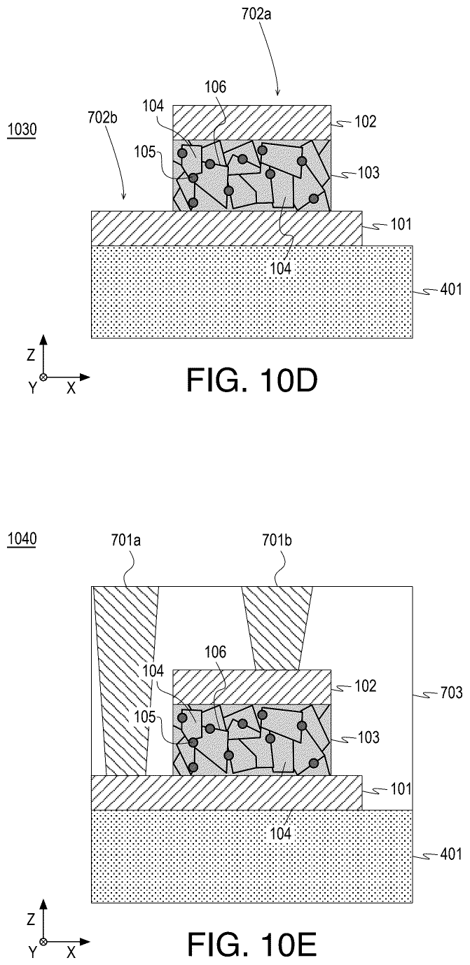

FIG. 9 is a flow diagram illustrating methods 900 for forming a capacitor having a polycrystalline dielectric material including an amorphous passivation material at grain boundaries of the polycrystalline dielectric material, arranged in accordance with some embodiments of the disclosure. Methods 900 may be practiced, for example, to fabricate any of the capacitors or capacitor structures discussed herein. FIGS. 10A, 10B, 10C, 10D, and 10E are cross-sectional views of capacitor structures evolving as methods 900 are practiced, arranged in accordance with some embodiments of the disclosure. Although illustrated with respect to fabrication of a plate capacitor, methods 900 may be used to form any capacitor structure. For example, methods 900 may be used to form deep trench capacitor 400, stacked capacitor structure 600, stacked capacitor structure 700, or any other capacitor structure discussed herein.

Methods 900 begin at input operation 901, where a workpiece including one or more material layers of a package substrate, for example, is received. In some embodiments, the workpiece is a large format substrate that may be segmented into portions for deployment in a package assembly. In some embodiments, the package substrate is a glass substrate or glass layer. Processing continues at operation 902, where a lower electrode layer is formed using any suitable technique or techniques such as blanket deposition techniques. The lower electrode layer may have any characteristics discussed with respect to electrode 101.

As shown in FIG. 10A, a capacitor structure 1000 includes a lower electrode material layer 1002 (as formed at operation 902), which is to become electrode 101 of a capacitor or capacitor structure. Electrode material layer 1002 may include any material, materials, or material stack as discussed herein with respect to electrodes 101, 102. Electrode material layer 1002 may be formed using any suitable technique or techniques such as blanket deposition techniques. The blanket deposition may be performed with a physical vapor deposition (PVD) process, a chemical vapor deposition (CVD) process, a plating process, or the like. In some embodiments, electrode material layer 1002 is substantially pure or pure titanium nitride. However other materials or material systems may be used. For example, electrode material layer 1002 may be or include silicon oxide, titanium oxide, tungsten, tantalum nitride, ruthenium, iridium, aluminum, copper, titanium, cobalt, chromium, molybdenum, nickel, gold, or platinum. As shown, lower electrode material layer 1002 may be formed on or over substrate 401. In some embodiments, lower electrode material layer 1002 is formed conformal to an opening in substrate 401 to form a deep trench capacitor (refer to FIG. 4).

Returning to FIG. 9, methods 900 continue at operation or operations 903, where a polycrystalline dielectric material including an amorphous passivation material at grain boundaries of the polycrystalline dielectric material is deposited using, for example, atomic layer deposition (ALD) processing. As shown, in some embodiments, operation or operations 903 include a number of sub-operations 904-909.

For example, formation of the dielectric material layer may commence with heating the substrate at operation 904 to a desired processing temperature such as a temperature of about 250° C. For example, the workpiece may be received and attached to a chuck which provides heating (e.g., via coils in the chuck) of the workpiece to the desired temperature.

Processing may then commence with cyclic ALD operations 905-909 with each cycle including one, some or all of, operations 905-909. As shown, operation 905 flows process gas including zirconium or hafnium and operation 906 flows process gas including ozone or oxygen. Such flows are into a sealed processing chamber including the workpiece and chuck. The zirconium or hafnium process gas flow attaches zirconium or hafnium atoms to the exposed surface of the workpiece. The subsequent ozone or oxygen process gas flow then reacts oxygen with the zirconium or hafnium atoms to form polycrystalline zirconium oxide or hafnium oxide. The feeding time, flow rate, and temperature may define a crystal size of the polycrystalline zirconium oxide or hafnium oxide. For example, higher temperature processing tends to increase grain size. Such process parameters may be optimized to form a polycrystalline material having the desired characteristics for a particular application. As shown with respect to process loop 908 such flowing of zirconium or hafnium followed by ozone or oxygen flow may be repeated any number of times to begin to form (and, later, continue to form) polycrystalline zirconium oxide or hafnium oxide.

After one or more cycles of zirconium or hafnium process gas flow followed by ozone or oxygen process gas flow, processing continues at operation 907 where a flow of a process gas including the passivation material is provided. In some embodiments, the process gas includes silicon to form silicon filter materials. In some embodiments, the process gas includes boron and nitrogen (or cycles of process gas including boron/nitrogen) to form boron nitride filler materials. In some embodiments, the process gas includes silicon, carbon, hydrogen, and oxygen (or cycles of the process gas including silicon/carbon/hydrogen/oxygen) to form carbon doped silicon oxide filler materials. Other dielectric the process gases may be used to form other amorphous filler materials. Furthermore, precursors and other reactants may be used in the ALD processing as is known in the art.

During ALD of such filler materials, the filler materials tend to merge and form along grain boundaries of the zirconium oxide or hafnium oxide as the lowest diffusion energy path of the deposited material. That is, the filler materials form at the desired location at grain boundaries in the polycrystalline zirconium oxide or hafnium oxide.

As discussed above, an important aspect of the polycrystalline dielectric material including grain boundary amorphous passivation materials is the volume fraction of passivation material in the dielectric material. The volume fraction of passivation material may be controlled by controlling the process parameters of operation 907 including flow rate, flow duration, and temperature, with flow duration being particularly impactful. In some embodiments, the processing of operation 907 is less than 3 seconds. In some embodiments, the processing of operation 907 is not less than 1 second and not more than 2 seconds. In addition, the frequency of deployment of operation 907 relative to cycles of operations 905 and 906 may be used to optimize the volume fraction and enhance location of the filler material at grain boundaries.

As discussed, cyclic ALD processing is used to inject amorphous material (i.e., filler material) into the grain boundaries of the capacitor dielectric material (e.g., the high-k dielectric grain boundaries). To prevent dielectric constant reduction of the capacitor dielectric material, the duty cycle of injection may be carefully controlled. Such duty cycle control and optimization maintains the crystalline phase of the crystalline grains of the polycrystalline capacitor dielectric material with low leakage current. Such passivation may be deployed in a single layer of capacitor dielectric material (i.e., high-k dielectric to maintain a high dielectric constant and lower leakage current performance. In particular, for DTC structures in advanced packaging contexts such as DTC on glass substrate, such single layer capacitor dielectric (in contrast to multilayer stacks) provide process simplicity, lower costs, and other advantages evident to those of skill in the art.

After operation 907, ALD processing continues along process loop 909 at operation 905 until ALD processing ends at any of operations 905, 906, 907, and methods 900 continue at operation 910.

FIG. 10B illustrates a capacitor structure 1010 similar to capacitor structure 1000 after blanket deposition of dielectric material 103 on or over electrode material layer 1002. Dielectric material 103 includes crystalline grains 104 separated by grain boundaries 106 and filler material 105 at grain boundaries 106. Dielectric material 103 may have any characteristic discussed herein. As shown, dielectric material 103 may be formed on electrode material layer 1002 and over substrate 401. In some embodiments, dielectric material 103 is formed conformally within to an opening in substrate 401 to form a deep trench capacitor (refer to FIG. 4).

Returning to FIG. 9, methods 900 continue at operation 910, where an upper electrode layer is formed using any suitable technique or techniques such as blanket deposition techniques. The upper electrode layer may have any characteristics discussed with respect to electrode 102.

FIG. 10C illustrates a capacitor structure 1020 similar to capacitor structure 1010 after formation of an upper electrode material layer 1021, which is to become electrode 102 of a capacitor or capacitor structure. Electrode material layer 1021 may include any material, materials, or material stack as discussed herein with respect to electrodes 101, 102. Electrode material layer 1021 may be formed using any suitable technique or techniques such as blanket deposition using PVD, CVD, or plating for example. In some embodiments, electrode material layer 1021 is substantially pure or pure titanium nitride. However other materials or material systems may be used. For example, electrode material layer 1021 may be or include silicon oxide, titanium oxide, tungsten, tantalum nitride, ruthenium, iridium, aluminum, copper, titanium, cobalt, chromium, molybdenum, nickel, gold, or platinum. As shown, upper electrode material layer 1021 may be formed on dielectric material 103 and over substrate 401. In some embodiments, upper electrode material layer 1021 is formed conformally within an opening in substrate 401 to form a deep trench capacitor (refer to FIG. 4).

Returning to FIG. 9, methods 900 continue at operation 911, where the capacitor material layers (e.g., lower electrode material layer, dielectric material, and lower electrode material layer) are patterned with any subtractive process(es) suitable for the various material layer compositions. Following capacitor patterning, any remaining interconnect levels of the integrated may be completed and the resultant structure maybe output at operation 912. For example, the electrodes of the capacitor may be connected to other circuit nodes using metal vias. The resultant device may be integrated in a package, assembly, system, or the like and deployed in any suitable electronics device.

FIG. 10D illustrates a capacitor structure 1030 similar to capacitor structure 1020 after operations, such as lithography and etch operations are performed to pattern electrodes 101, 102 and dielectric material 103. As shown, such patterning provides regions 702a, 702b for landing metal vias.

FIG. 10E illustrates a capacitor structure 1040 similar to capacitor structure 1030 after formation of metal vias 701a, 701b and insulator material 703. In some embodiments, a bulk layer of insulator material 703 is deposited and planarized, and then patterned with openings corresponding to metal vias 701a, 701b. The openings may then be filled with metal and polished to form metal vias 701a, 701b. Other fabrication techniques may be used.

The capacitor structures discussed herein may be deployed in any suitable architecture, device, or system.

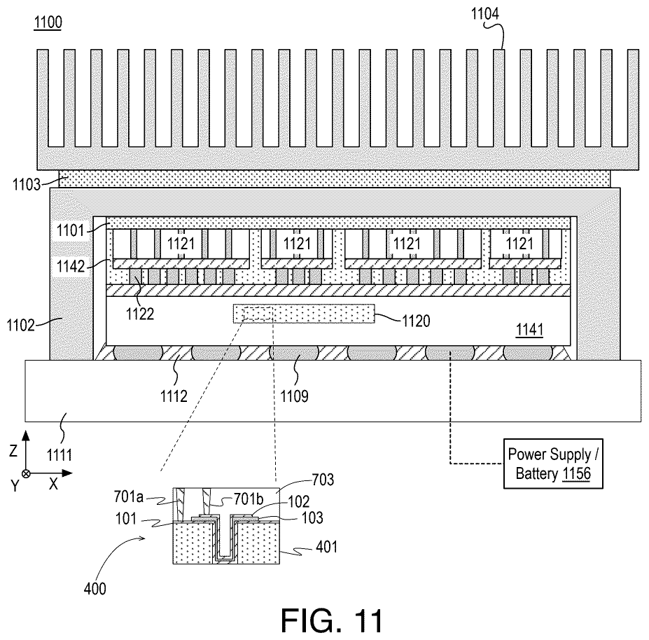

FIG. 11 illustrates an example microelectronic device assembly 1100 including a component 1120 that includes a capacitor having a polycrystalline dielectric material including an amorphous passivation material at grain boundaries of the polycrystalline dielectric material, in accordance with some embodiments. As shown, deep trench capacitor 400 or any other capacitor or capacitor structure discussed herein may be incorporated into microelectronic device assembly 1100. Microelectronic device assembly 1100 includes any number of IC dies 1121 mounted by device level interconnects 1122 to a substrate 1141, which may be a package substrate, interposer, board, or the like. IC dies 1121 may be embedded in fill material 1142. Substrate 1141 is coupled, via interconnects 1109, which are optionally embedded in a mold or underfill material 1112 to a microelectronics board 1111 such as a motherboard. Although illustrated with respect to component 1120 being embedded in substrate 1141, component 1120 may be deployed in microelectronic device assembly 1100 in any context such as being mounted to an upper or lower surface of substrate 1141 or microelectronics board 1111. Alternatively, deep trench capacitor 400 or any other capacitor or capacitor structure discussed herein may be incorporated in any one of IC dies 1121 or as a discrete device on or over substrate 1141 or microelectronics board 1111.

Microelectronic device assembly 1100 further includes a power supply 1156 coupled to one or more of microelectronics board 1111, substrate 1141 (i.e., a board, package substrate, or interposer), IC dies 1121 and/or other components of microelectronic device assembly 1100. Power supply 1156 may include a battery, voltage converter, power supply circuitry, or the like. Microelectronic device assembly 1100 further includes a thermal interface material (TIM) 1101 disposed on top surfaces of IC dies 1121 (or on another structure such as a structural substrate that is on top surfaces of IC dies 1121). TIM 1101 may include any suitable thermal interface material and may be characterized as TIM 1. Integrated heat spreader 1102 having a surface on TIM 1101 extends over IC dies 1121 and is mounted to microelectronics board 1111. Microelectronic device assembly 1100 further includes a TIM 1103 disposed on a top surface of integrated heat spreader 1102. TIM 1103 may include any suitable thermal interface material and may be characterized as TIM 2. TIM 1101 and TIM 1103 may be the same materials, or they may be different. A heat sink 1104 (e.g., an exemplary heat dissipation device or thermal solution) is on TIM 1103 and dissipates heat. Microelectronic device assembly 1100 may be used in desktop and server form factors. In other contexts, a heat solution such as a heat pipe or heat spreader may be mounted directly on TIM 1101. Such assemblies may be used in smaller form factor devices. Other heat dissipation devices may be used.

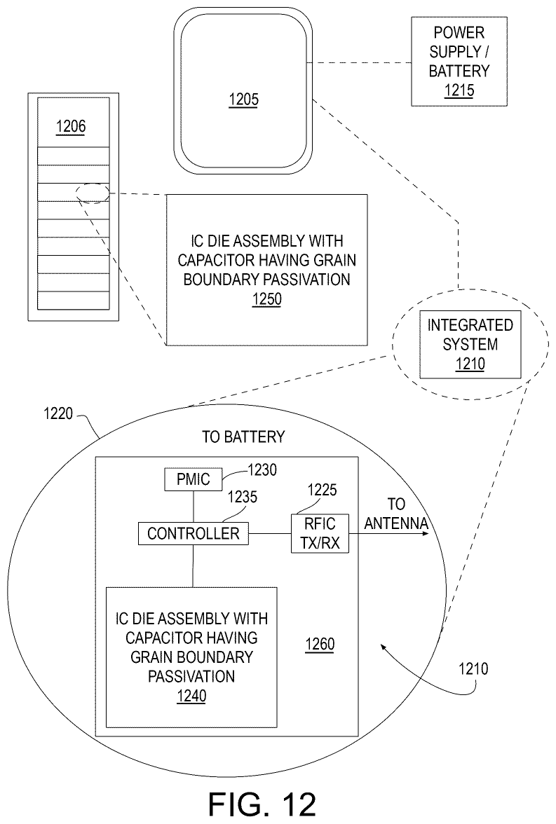

FIG. 12 illustrates exemplary systems employing a capacitor with a capacitor dielectric having passivation boundary defects to reduce leakage current, in accordance with some embodiments. The system may be a mobile computing platform 1205 and/or a data server machine 1206, for example. Either may employ a module, capacitor, or the like having a capacitor with a capacitor dielectric having passivation boundary defects to reduce leakage current as described elsewhere herein. Server machine 1206 may be any commercial server, for example including any number of high-performance computing platforms disposed within a rack and networked together for electronic data processing, which in the exemplary embodiment includes an IC die assembly 1250 with a capacitor with a capacitor dielectric having passivation boundary defects to reduce leakage current as described elsewhere herein. Mobile computing platform 1205 may be any portable device configured for each of electronic data display, electronic data processing, wireless electronic data transmission, or the like. For example, mobile computing platform 1205 may be any of a tablet, a smart phone, a laptop computer, etc., and may include a display screen (e.g., a capacitive, inductive, resistive, or optical touchscreen), a chip-level or package-level integrated system 1210, and a power supply/battery 1215. Although illustrated with respect to mobile computing platform 1205, in other examples, chip-level or package-level integrated system 1210 and a power supply/battery 1215 may be implemented in a desktop computing platform, an automotive computing platform, an internet of things platform, or the like. As discussed below, in some examples, the disclosed systems may include a sub-system 1260 such as a system on a chip (SOC) or an integrated system of multiple ICs, which is illustrated with respect to mobile computing platform 1205.

Whether disposed within integrated system 1210 illustrated in expanded view 1220 or as a stand-alone packaged device within data server machine 1206, sub-system 1260 may include memory circuitry and/or processor circuitry 1240 (e.g., RAM, a microprocessor, a multi-core microprocessor, graphics processor, etc.), a power management integrated circuit (PMIC) 1230, a controller 1235, and a radio frequency integrated circuit (RFIC) 1225 (e.g., including a wideband RF transmitter and/or receiver (TX/RX)). As shown, one or more IC dice, such as memory circuitry and/or processor circuitry 1240 may be assembled and implemented such that one or more assembly includes a capacitor with a capacitor dielectric having passivation boundary defects to reduce leakage current as described herein. In some embodiments, RFIC 1225 includes a digital baseband and an analog front end module further comprising a power amplifier on a transmit path and a low noise amplifier on a receive path). Functionally, PMIC 1230 may perform battery power regulation, DC-to-DC conversion, etc., and so has an input coupled to power supply/battery 1215, and an output providing a current supply to other functional modules. As further illustrated in FIG. 12, in the exemplary embodiment, RFIC 1225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1240 may provide memory functionality for sub-system 1260, high level control, data processing and the like for sub-system 1260. In alternative implementations, each of the SOC modules may be integrated onto separate ICs coupled to a package substrate, interposer, or board.

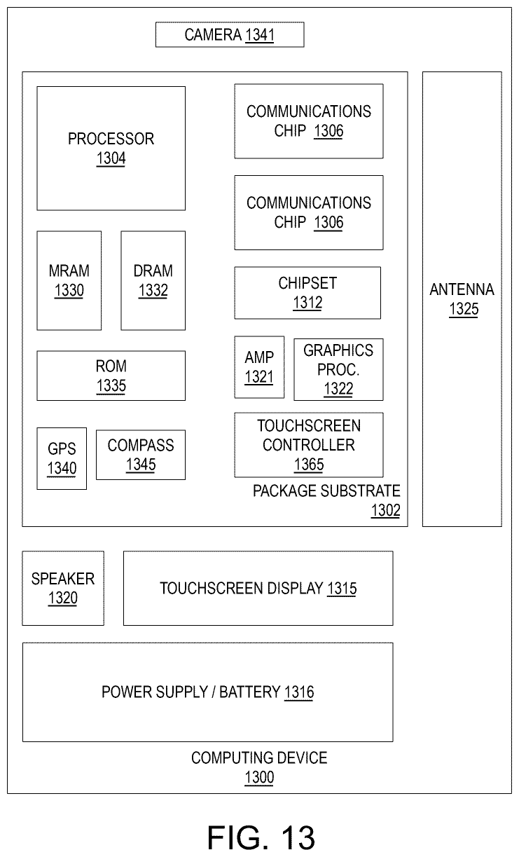

FIG. 13 is a functional block diagram of an electronic computing device 1300, in accordance with some embodiments. For example, device 1300 may, via any suitable component therein, employ a capacitor with a capacitor dielectric having passivation boundary defects to reduce leakage current in accordance with any embodiments described elsewhere herein. Device 1300 further includes a motherboard or package substrate 1302 hosting a number of components, such as, but not limited to, a processor 1304 (e.g., an applications processor). Processor 1304 may be physically and/or electrically coupled to package substrate 1302. In some examples, processor 1304 is within an IC assembly that includes a capacitor with a capacitor dielectric having passivation boundary defects to reduce leakage current as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1306 may also be physically and/or electrically coupled to the package substrate 1302. In further implementations, communication chips 1306 may be part of processor 1304. Depending on its applications, computing device 1300 may include other components that may or may not be physically and electrically coupled to package substrate 1302. These other components include, but are not limited to, volatile memory (e.g., DRAM 1332), non-volatile memory (e.g., ROM 1335), flash memory (e.g., NAND or NOR), magnetic memory (MRAM 1330), a graphics processor 1322, a digital signal processor, a crypto processor, a chipset 1312, an antenna 1325, touchscreen display 1315, touchscreen controller 1365, power supply/battery 1316, audio codec, video codec, power amplifier 1321, global positioning system (GPS) device 1340, compass 1345, accelerometer, gyroscope, speaker 1320, camera 1341, and mass storage device (such as hard disk drive, solid-state drive (SSD), compact disk (CD), digital versatile disk (DVD), and so forth, or the like.

Communication chips 1306 may enable wireless communications for the transfer of data to and from the computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1306 may implement any of a number of wireless standards or protocols, including, but not limited to, those described elsewhere herein. As discussed, computing device 1300 may include a plurality of communication chips 1306. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first electrode, a second electrode, a dielectric material between the first electrode and the second electrode, the dielectric material comprising a plurality of grains having grain boundaries therebetween and a filler material at one of the grain boundaries, wherein each of the plurality of grains has a first composition comprising oxygen and one of hafnium or zirconium, and the filler material has a second composition.

In one or more second embodiments, further to the first embodiments, the first composition comprises at least twenty percent hafnium or zirconium and at least twenty percent oxygen.

In one or more third embodiments, further to the first or second embodiments, the filler material comprises not less than ninety percent silicon.

In one or more fourth embodiments, further to the first through third embodiments, the second composition comprises one of boron nitride, carbon doped silicon oxide, or pure silicon.

In one or more fifth embodiments, further to the first through fourth embodiments, each of the plurality of grains comprises crystalline hafnium dioxide or crystalline zirconium dioxide and the filler material comprises an amorphous material.

In one or more sixth embodiments, further to the first through fifth embodiments, the filler material comprises pure silicon.

In one or more seventh embodiments, further to the first through sixth embodiments, a volume fraction of the filler material in the dielectric material is not less than 0.5 percent and not more than 7 percent.

In one or more eighth embodiments, further to the first through seventh embodiments, the first electrode comprises one of titanium, silicon, ruthenium, or iridium.

In one or more ninth embodiments, further to the first through eighth embodiments, the apparatus further comprises a solid layer of glass, wherein at least portions of the first electrode, the second electrode, and the dielectric material are within an opening in the solid layer of glass.

In one or more tenth embodiments, further to the first through ninth embodiments, the apparatus further comprises a power supply coupled to the first electrode or the second electrode.

In one or more eleventh embodiments, further to the first through ninth embodiments, a system comprises a capacitor according to any of the apparatuses of the first through ninth embodiments, and a power supply coupled to the capacitor.

In one or more twelfth embodiments, an apparatus comprises a first electrode, a second electrode, and a dielectric material between the first electrode and the second electrode, the dielectric material comprising a plurality of crystalline grains each having a first composition and an amorphous filler material having a second composition, wherein the amorphous filler material is located at a grain boundary between a first crystalline grain of the plurality of crystalline grains and a second crystalline grain of the plurality of crystalline grains.

In one or more thirteenth embodiments, further to the twelfth embodiments, the first composition comprises not less than sixty percent oxygen and not less than thirty percent hafnium or zirconium.

In one or more fourteenth embodiments, further to the twelfth or thirteenth embodiments, the second composition comprises not less than ninety percent silicon.

In one or more fifteenth embodiments, further to the twelfth through fourteenth embodiments, a volume fraction of the amorphous filler material in the dielectric material is not less than 0.5 percent and not more than 7 percent.

In one or more sixteenth embodiments, further to the twelfth through fifteenth embodiments, the apparatus further comprises a solid layer of glass, wherein at least portions of the first electrode, the second electrode, and the dielectric material are within an opening in the solid layer of glass, and a power supply coupled to the first electrode or the second electrode.

In one or more eighteenth embodiments, further to the twelfth through fifteenth embodiments, a system comprises a capacitor according to any of the apparatuses of the first through ninth embodiments, and a power supply coupled to the capacitor.

In one or more nineteenth embodiments, a method comprises forming a bottom electrode layer over a substrate, depositing a dielectric material layer over the bottom electrode layer via atomic layer deposition (ALD), the ALD comprising a plurality of cycles of application of zirconium or hafnium, followed by application of ozone or oxygen, followed by application of a material other than zirconium and hafnium, and forming a top electrode layer over the dielectric material layer.

In one or more twentieth embodiments, further to the nineteenth embodiments, application of the material other than zirconium and hafnium comprises application of silicon.

In one or more twenty-first embodiments, further to the nineteenth or twentieth embodiments, the method further comprises a plurality of intermediary cycles immediately following a first cycle of the plurality of cycles and immediately preceding a second cycle of the plurality of cycles, the plurality of intermediary cycles each consisting of application of zirconium or hafnium immediately followed by application of ozone or oxygen.

In one or more twenty-second embodiments, further to the nineteenth through twenty-first embodiments, the method further comprises heating, prior to deposition of the dielectric material layer, the substrate to a temperature of not less than 200° C.

In one or more twenty-third embodiments, further to the nineteenth through twenty-second embodiments, the substrate comprises a solid layer of glass, and the method further comprises forming a via opening within the solid layer of glass, wherein the bottom electrode, dielectric material layer, and top electrode are formed at least partially within the via opening to form a deep trench capacitor structure.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first electrode;
a second electrode; and
a dielectric material between the first electrode and the second electrode, the dielectric material comprising a plurality of grains having grain boundaries therebetween and a filler material at one of the grain boundaries, wherein each of the plurality of grains has a first composition comprising oxygen and one of hafnium or zirconium, and the filler material has a second composition.

2. The apparatus of claim 1, wherein the first composition comprises at least twenty percent hafnium or zirconium and at least twenty percent oxygen.

3. The apparatus of claim 2, wherein the filler material comprises not less than ninety percent silicon.

4. The apparatus of claim 1, wherein the second composition comprises one of boron nitride, carbon doped silicon oxide, or pure silicon.

5. The apparatus of claim 1, wherein each of the plurality of grains comprises crystalline hafnium dioxide or crystalline zirconium dioxide and the filler material comprises an amorphous material.

6. The apparatus of claim 5, wherein the filler material comprises pure silicon.

7. The apparatus of claim 1, wherein a volume fraction of the filler material in the dielectric material is not less than 0.5 percent and not more than 7 percent.

8. The apparatus of claim 1, wherein the first electrode comprises one of titanium, silicon, ruthenium, or iridium.

9. The apparatus of claim 1, further comprising:
a solid layer of glass, wherein at least portions of the first electrode, the second electrode, and the dielectric material are within an opening in the solid layer of glass.

10. The apparatus of claim 9, further comprising:
a power supply coupled to the first electrode or the second electrode.

11. An apparatus, comprising:
a first electrode;
a second electrode; and
a dielectric material between the first electrode and the second electrode, the dielectric material comprising a plurality of crystalline grains each having a first composition and an amorphous filler material having a second composition, wherein the amorphous filler material is located at a grain boundary between a first crystalline grain of the plurality of crystalline grains and a second crystalline grain of the plurality of crystalline grains.

12. The apparatus of claim 11, wherein the first composition comprises not less than sixty percent oxygen and not less than thirty percent hafnium or zirconium.

13. The apparatus of claim 12, wherein the second composition comprises not less than ninety percent silicon.

14. The apparatus of claim 12, wherein a volume fraction of the amorphous filler material in the dielectric material is not less than 0.5 percent and not more than 7 percent.

15. The apparatus of claim 11, further comprising:
a solid layer of glass, wherein at least portions of the first electrode, the second electrode, and the dielectric material are within an opening in the solid layer of glass; and
a power supply coupled to the first electrode or the second electrode.

16. A method, comprising,
forming a bottom electrode layer over a substrate;
depositing a dielectric material layer over the bottom electrode layer via atomic layer deposition (ALD), the ALD comprising a plurality of cycles of application of zirconium or hafnium, followed by application of ozone or oxygen, followed by application of a material other than zirconium and hafnium;
forming a top electrode layer over the dielectric material layer.

17. The method of claim 16, wherein application of the material other than zirconium and hafnium comprises application of silicon.

18. The method of claim 16, wherein the method further comprises a plurality of intermediary cycles immediately following a first cycle of the plurality of cycles and immediately preceding a second cycle of the plurality of cycles, the plurality of intermediary cycles each consisting of application of zirconium or hafnium immediately followed by application of ozone or oxygen.

19. The method of claim 16, further comprising:
heating, prior to deposition of the dielectric material layer, the substrate to a temperature of not less than 200° C.

20. The method of claim 16, wherein the substrate comprises a solid layer of glass, the method further comprising:
forming a via opening within the solid layer of glass, wherein the bottom electrode, dielectric material layer, and top electrode are formed at least partially within the via opening to form a deep trench capacitor structure.
